(19) United States
(12) Patent Application Publication
(10) Pub. No.: US 2009/0238444 A1
(43) Pub. Date: Sep. 24, 2009

(54) OPTICAL IMAGING APPARATUS AND METHOD FOR INSPECTING SOLAR CELLS

(75) Inventors: CHIA HO SU, Kaohsiung City (TW); WEN SHENG LIN, Hsinchu County (TW); KUANG YU CHEN, Hsinchu County (TW)

Correspondence Address: WPAT, PC;INTELLECTUAL PROPERTY ATTORNEYS, 2030 MAIN STREET, SUITE 1300, IRVINE, CA, 92614, US

(73) Assignee: VISWELL TECHNOLOGY CO., LTD, HSINCHU COUNTY (TW)

(21) Appl. No.: 12/169,251

(22) Filed: Jul. 8, 2008

(30) Foreign Application Priority Data
Mar. 19, 2008 (TW) 097109594

(51) Int. Cl. G06K 9/00

(52) U.S. Cl. 382/149

(57) ABSTRACT

An optical imaging apparatus for inspecting a solar cell includes a power supply configured to apply a reverse biased voltage to the solar cell such that shunt defects in the solar cell will generate heat, a thermal imaging device configured to obtain the thermal image of the solar cell, a computing unit including a thermal image analysis module configured to identify hot spots in the thermal image, a locating module configured to locate the center positions of the hot spots, a visible image analysis module configured to identify the defect features of the hot spots, and a visible light imaging device configured to acquire visible images of the hot spots.

### BACKGROUND OF THE INVENTION

1. Field of the Invention

The present invention relates generally to an optical imaging apparatus and method for inspecting solar cells, and more particularly to an optical imaging apparatus and method for inspecting solar cells by thermal imaging biased solar cells and performing inspections of the defects by the visible imaging technique.

2. Description of the Related Art

Photovoltaic systems, such as conventional solar cells, directly convert sunlight into electrical energy using the principles of the photovoltaic conversion. The conversion efficiency has a direct influence on the output of electrical power, and it is also one of primary factors that determine the price of the solar cell. After manufacturing, solar cells will be tested to determine their conversion efficiency. Greater conversion efficiency results in higher selling prices. So, if a solar cell manufacturer wants to attain the most economical production, the manufacturing process of solar cells must be maintained at a high level of quality. A key factor for high-quality production is a high-speed, high-throughput and high-precision inspection apparatus for solar cell testing and screening.

During production inspection, a manufacturer screens solar cells preliminarily, and then performs optical inspections, during which defective solar cells are screened out. This inspection process will lower the inspection time, increase the throughput, improve the process stability and, more important, lower the cost of manufacture. The current optical inspection technology for solar cells is not able to fulfill the inspection requirements for high quality manufacture in a mass-production line without increasing budget. In view of the manufacturing cost, it is essential to have an inspection with screening capability.

Defects or cracks in solar cells have the potential to severely limit the power output of a solar cell. Significant defects or cracks may even cause shorts or shunts. Current optical inspection apparatus may not be able to find all defects or cracks critical to solar cells in a mass production line, particularly those defects or cracks which are very small or hidden under the surface of the solar cells.

In view of the above-mentioned problems and requirements, a solar cell inspection apparatus that can improve inspection throughput and perform fast defect inspection is necessarily required by the solar cell industry.

### SUMMARY OF THE INVENTION

The present invention proposes an optical imaging apparatus for inspecting a solar cell, which comprises a power supply, a thermal imaging device and a computing unit. The power supply is configured to apply a reverse biased voltage to the solar cell. The thermal imaging device is configured to obtain a thermal image of the solar cell. The computing unit includes a thermal image analysis module configured to identify hot spots in the thermal image, a locating module configured to locate the center positions of the hot spots and a visible image analysis module configured to identify the defect features of the hot spots.

In one embodiment, the reverse biased voltage is the breakdown voltage of the p-n junctions of the solar cell. The temperatures of the hot spots are higher than a temperature threshold, and the sizes of the hot spots are larger than an area threshold.

The method for inspection of solar cells by an optical imaging inspection apparatus comprises the steps of: applying a reverse biased voltage to a solar cell; acquiring a thermal image of the solar cell by a thermal imaging device; and identifying a hot spot with a temperature higher than a temperature threshold and a size larger than an area threshold.

### BRIEF DESCRIPTION OF THE DRAWINGS

The invention will be described according to the appended drawings in which:

FIG. 1 is a perspective view of the optical imaging inspection apparatus according to one embodiment of the present invention;

FIG. 2 is a side view of the laser pointer and the visible light imaging device arrangement according to one embodiment of the present invention;

FIG. 3 shows a side view of the optical imaging inspection apparatus according to another embodiment of the present invention; and

FIG. 4 is a flow chart of a method for inspecting a solar cell according to one embodiment of the present invention.

### DETAILED DESCRIPTION OF THE INVENTION

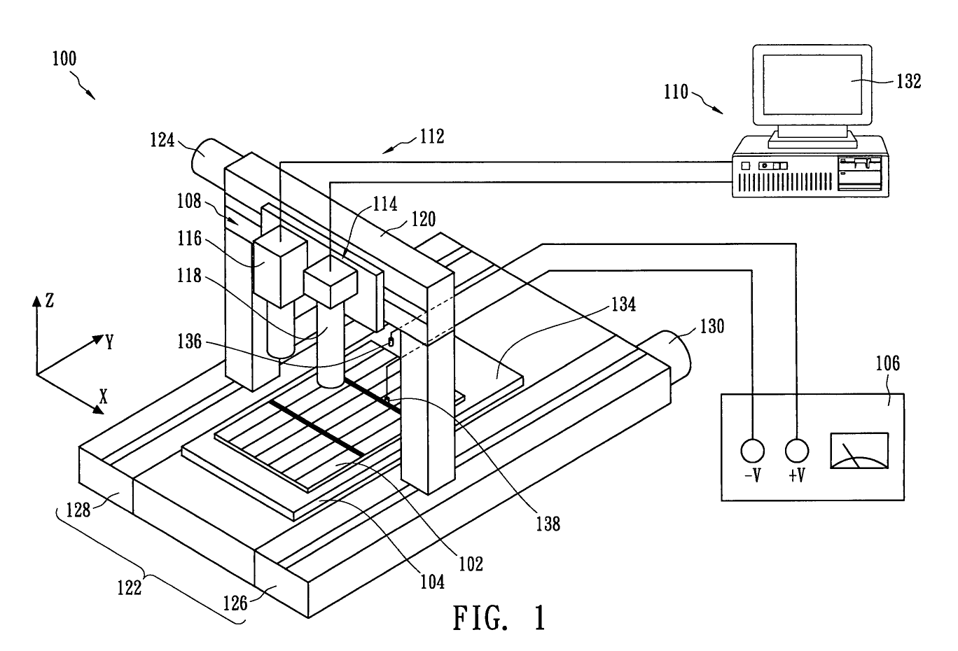

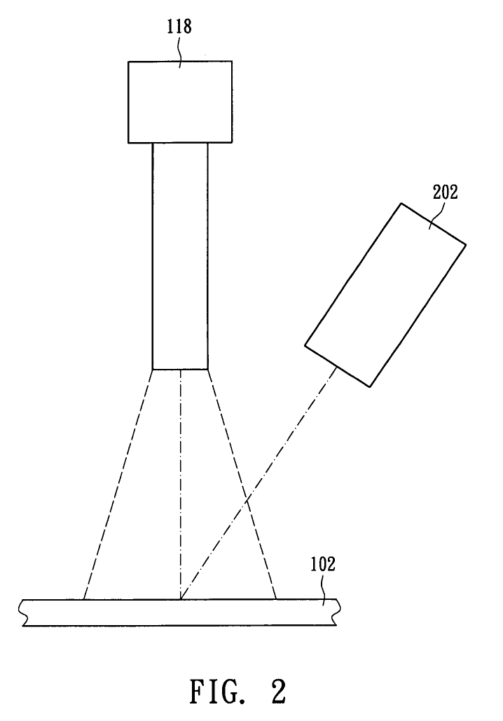

FIG. 1 and FIG. 2 illustrate an optical imaging apparatus 100 for inspecting a solar cell 102 according to one embodiment of the present invention. During inspection, the solar cell 102 is held and electrically coupled on the stage 104 of the optical imaging apparatus 100. A power supply 106 connected with the stage 104 and the solar cell 102 is used to provide a reverse-biased voltage to the solar cell 102 to increase its temperature. Some defects in the solar cell 102 generate heat locally under the reversed-biased voltage. A thermal imaging device 108, used to obtain the thermal images of the solar cell 102, includes an infrared camera 116, which is coupled to a computing unit 110. The computing unit 110 can extract, identify and locate the positions of the hot spots caused by defect heating effect. If there are hot spots, the computing unit 110 will also calculate the center positions of those hot spots.

Referring to FIG. 1, the stage 104 has a metal surface 134, which is electrically coupled to the negative contact of the solar cell 102 held by the stage 104. The power supply 106 connects and applies a positive voltage at a terminal 136 on the metal surface 134 and a negative voltage at the positive output line 138 of the solar cell 102. Such type of connection causes the solar cell 102 to be in a reverse biased condition. Some defects in the solar cell 102 will generate heat and become hot spots after the reverse biased voltage is applied. The reverse biased voltage may be, for example, the breakdown voltage across the p-n junctions of the solar cell 102.

Referring primarily to FIG. 1 and FIG. 2, the optical imaging inspection apparatus 100 also includes a visible light-imaging device 114, which is used to capture the images of defects. The visible light-imaging device 114 comprises a camera, which is coupled to the computing unit 110. Various cameras may be used including Linescan camera, area camera, CCD or CMOS camera. The defect images captured by the visible light imaging device 114 are analyzed by a visible image analysis module. The visible image analysis module identifies the defect features, performs statistical analysis, and stores the statistical results in a statistical database. If the defects are very tiny, those images will be captured at high magnification. At high magnification, the camera 118 has a narrow field of view, and it is not easy to know the position to which the camera 118 is directed. Under this circumstance, a laser pointer 202 can be utilized for helping a user know the position at which the camera 118 is directed or where the location is on the solar cell 102 corresponding to the center of the captured visible image of the camera 118, as illustrated in FIG. 2.

Referring again to FIG. 1, the computing unit 110 comprises a thermal image analysis module, a visible image analysis module, and a locating module. The thermal image analysis module identifies hot spots having temperatures higher than a temperature threshold and sizes larger than an area threshold. The locating module calculates the coordinates of the centers of hot spots, and the distances between the hot spots and the camera 118. The temperature and area thresholds may be set by an operator or by predetermined default values. The default value of the minimum area threshold can be, for example, 1 pixel. Use of edge detection techniques or binarizing method can identify or extract hot spots. The edge detection method may be, for example, a first-order edge detection approach or a second-order edge detection approach. The binarizing method may include a fixed threshold scheme or an adaptive threshold scheme. The hot-spot temperature may be defined as, for example, the highest, median, mode, or average temperature. The computing unit 110 determines hot spots by following steps: the thermal image analysis module identifies hot spots by using an edge detection technique and then determines which hot spots exceed the thresholds, and finally the locating module calculates the centers of the hot spots by using, for example, centroid calculation method. The visible image analysis module may have, for example, the following recognition procedures: the module acquires a visible defect image, and extracts the features of the image for their templates, and compares the templates of the image with the templates stored in a database, and finally declares a match. The computing unit 110 further comprises a display 132 showing the image captured by the thermal imaging device 108 or the visible light imaging device 114.

Referring again to FIG. 1, a drive module 112 is used to move the thermal imaging device 108 attached thereon around the stage 104 while capturing images. The drive module 112 is used to drive the visible light-imaging device 114 to the center positions of hot spots for capturing the visible defect images in sequence. The drive module 112 includes an x-motion unit 120 and a y-motion assembly 122, and hence the drive module 112 is able to provide motion in X and Y directions. The x-motion unit 120 may be driven by a motor 124 and ball screw combination as illustrated in FIG. 1, or by a driver system such as linear motor, a belt of chain drive slide system, and the like. The y-motion assembly 122 comprises a y-motion unit 126 and a motion guide unit 128. The y-motion unit 126 may be driven by a motor 130 and ball screw combination as illustrated in FIG. 1, or by a driver system such as linear motor, a belt of chain drive slide system, and the like. The motion guide unit 128 may be, for example, a rail guide assembly and the like.

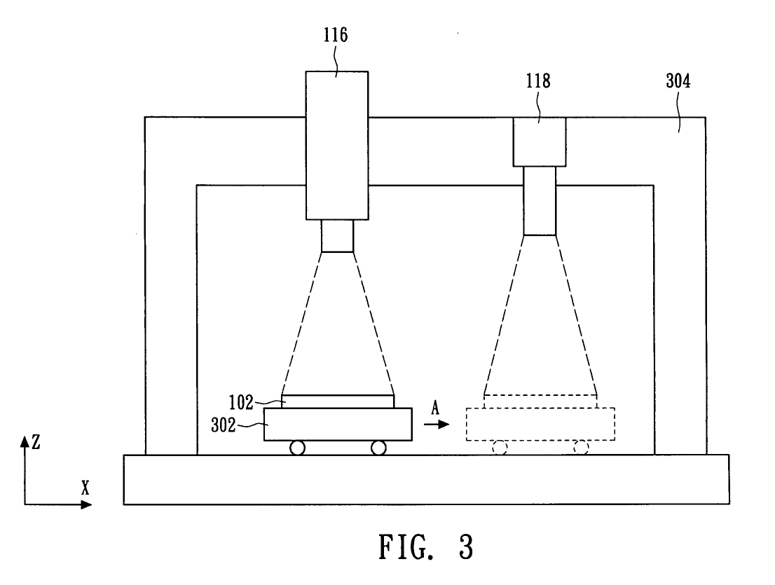

FIG. 3 shows a side view of the optical imaging inspection apparatus according to another embodiment of the present invention. In this embodiment, an infrared camera 116 and an optical camera 118 are attached to a fixed frame 304, and a moving stage 302 holding a solar cell 102 moves around to perform inspection. After the infrared camera 116 finishes capturing the thermal images of the solar cell 102 held by the moving stage 302, the moving stage 302 will move in a direction, as illustrated by the arrow A, to the location below the optical camera 118, and position the centers of the hot spots one after another in sequence to the optical camera 118 to capture the visible defect images. The moving stage 302 can move in X and Y directions and may include an XY moving stage or the like. Automatic driving forces or manual driving forces may be used to drive the moving stage 302.

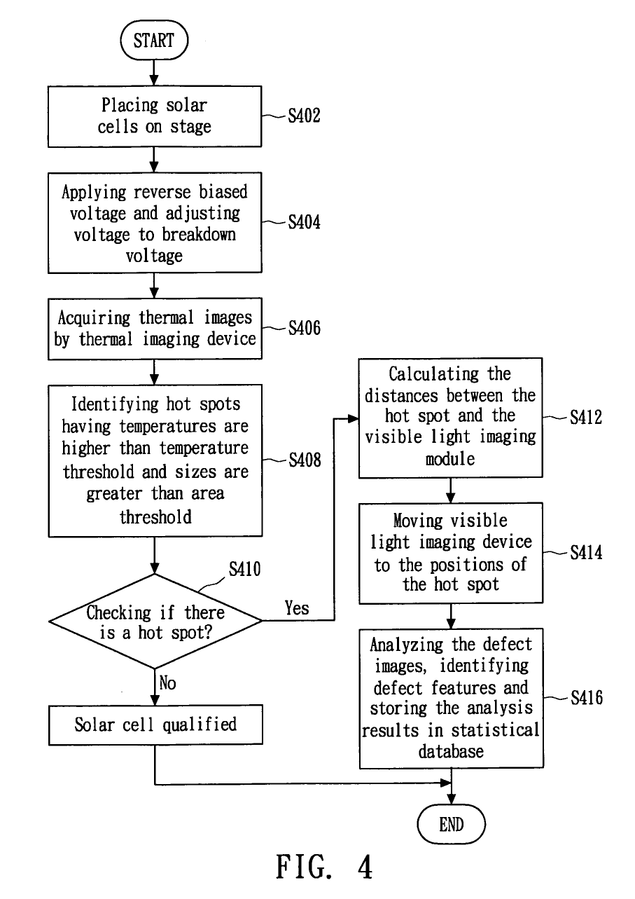

FIG. 4 is a flow chart of a method for inspecting a solar cell according to one embodiment of the present invention. In Step S402, the solar cell, which is undergoing inspection, is placed on the stage of the optical imaging inspection apparatus. The negative contact of the solar cell is electrically coupled to the metal surface of the stage so that electricity can pass through the metal surface to the solar cell. In Step S404, a power supply connects and applies a positive voltage at a terminal on the metal surface of the solar cell and a negative voltage at the positive output line of the solar cell. The output voltage of the power supply is adjusted steadily to the breakdown voltage across the p-n junctions of the solar cell. In Step S406, the thermal imaging device obtains the thermal images of the solar cell, which generates heat in response to the reverse biased voltage. In Step S408, the thermal image analysis module of the computing unit identifies hot spots having temperatures higher than a temperature threshold and sizes larger than an area threshold. In Step S410, if no defects are detected, the solar cell is qualified and the inspection is stopped. In Step S412, the locating module of the computing module calculates the center coordinates of hot spots, and then calculates the distances between the hot spots and the optical camera. In Step S414, the visible light-imaging device is moved to the center positions of the hot spots and captures the visible image of the defects in sequence. In Step S416, the visible image analysis module analyzes the defect images captured by the visible light-imaging device. The module identifies the defect features, performs statistical analysis and stores the statistical results in a statistical database.

The above-described embodiments of the present invention are intended to be illustrative only. Numerous alternative embodiments may be devised by persons skilled in the art without departing from the scope of the following claims.

What is claimed is:

1. An optical imaging apparatus for inspecting a solar cell, comprising:
a power supply configured to apply a reverse biased voltage to the solar cell;
a thermal imaging device configured to obtain a thermal image of the solar cell; and
a computing unit including a thermal image analysis module configured to identify a hot spot in the thermal image and a locating module configured to locate the hot spot.

2. The apparatus of claim 1, wherein the temperature of the hot spot is higher than a temperature threshold and the size of the hot spot is greater than an area threshold.

3. The apparatus of claim 1, further comprising a drive module configured to move the thermal imaging device.

4. The apparatus of claim 1, wherein the reverse biased voltage is the breakdown voltage of the p-n junctions of the solar cell.

5. The apparatus of claim 1, further comprising a visible light imaging device configured to obtain a visible image of the hot spot.

6. The apparatus of claim 5, wherein the computing unit further comprises a visible image analysis module configured to identify the defect feature of the hot spot.

7. The apparatus of claim 5, further comprising a drive module configured to move the thermal imaging device and the visible light imaging device.

8. The apparatus of claim 5, further comprising a display for showing the image obtained by the thermal imaging device or the visible light imaging device.

9. The apparatus of claim 5, wherein the visible light imaging device comprises a camera.

10. The apparatus of claim 9, wherein the camera is linescan camera, area camera, CCD or CMOS camera.

11. The apparatus of claim 9, further comprising a laser pointer for pointing the location of the solar cell corresponding to the center of the visible image.

12. The apparatus of claim 1, further comprising a moving stage configured to move the solar cell.

13. The apparatus of claim 12, wherein the moving stage is an XY moving stage.

14. The apparatus of claim 12, wherein the moving stage is driven by automatic driving forces or manual driving forces.

15. A method for inspecting a solar cell, comprising the steps of:
applying a reverse biased voltage to the solar cell;
obtaining a thermal image of the solar cell by a thermal imaging device; and
identifying a hot spot having a temperature higher than a temperature threshold and a size larger than an area threshold.

16. The method of claim 15, further comprising the steps of:
calculating a center position of the hot spot;
obtaining a visible image of the hot spot by a visible light imaging device according to the center position;
identifying a defect feature of the hot spot; and
storing an analysis result of the defect feature in a statistical database.

17. The method of claim 16, wherein the reverse biased voltage is the breakdown voltage of p-n junctions.
